(19) United States
(12) Patent Application Publication
(10) Pub. No.: US 2025/0343443 A1
(43) Pub. Date: Nov. 6, 2025

(54) WIRELESS POWER TRANSMISSION DEVICE

(71) Applicant: SAMSUNG ELECTRONICS CO., LTD., Suwon-si (KR)

(72) Inventors: Jaehyun PARK, Suwon-si (KR); Minbeom KO, Suwon-si (KR); Beomwoo GU, Suwon-si (KR); Jaeseok PARK, Suwon-si (KR); Sungku YEO, Suwon-si (KR); Hyoseok HAN, Suwon-si (KR)

(73) Assignee: SAMSUNG ELECTRONICS CO., LTD., Suwon-si (KR)

(21) Appl. No.: 19/271,169

(22) Filed: Jul. 16, 2025

Related U.S. Application Data
(63) Continuation of application No. PCT/KR2024/000757, filed on Jan. 16, 2024.

(30) Foreign Application Priority Data
Jan. 16, 2023 (KR) 10-2023-0006350

(51) Int. Cl. H02J 50/12; H02J 7/00; H02J 50/00; H02J 50/40

(52) U.S. Cl. CPC H02J 50/12; H02J 7/0013; H02J 7/0044; H02J 50/005; H02J 50/40

(57) ABSTRACT

A wireless power transmission device may include: a first resonator including a first housing and a first coil inside the first housing, the first resonator being configured to wireless transmit power to an electronic device via magnetic resonance; and a second resonator including a second housing around at least a portion of the first housing, and a second coil inside the second housing, the second resonator being configured to wireless transmit power to the electronic device via the magnetic resonance, in a state in which the second resonator is coupled to the first resonator.

### CROSS-REFERENCE TO RELATED APPLICATIONS

This application is a bypass continuation application of International Application No. PCT/KR2024/000757, filed on Jan. 16, 2024, which claims priority to Korean Patent Application No. 10-2023-0006350, filed on Jan. 16, 2023, in the Korean Intellectual Property Office, the disclosures of which are incorporated by reference herein in their entireties.

### BACKGROUND

### 1. Field

The disclosure relates to a wireless power transmission device for wireless charging of an electronic device.

### 2. Description of Related Art

Wireless charging technology, which uses wireless power transmission and reception, refers to, for example, a technology of automatically charging a battery of a portable phone by simply placing the portable phone on a wireless power transmission device (e.g., a charging pad) without connecting the portable phone to a separate charging connector. This wireless charging technology may enhance waterproofing due to no need for a connector for supplying power to an electronic product and increase the portability of an electronic device due to no need for a wired charger. Along with the recent development of wireless charging technology, methods of supplying power to various different electronic devices (wireless power reception devices) and charging them with the power by a single electronic device (a wireless power transmission device) are under study.

For example, wireless charging technology includes an electromagnetic induction scheme. In a power transmission method based on electromagnetic induction, power is transmitted by utilizing a magnetic induction phenomenon between a primary coil and a secondary coil. When an AC current flows through the primary coil, a time-varying magnetic field is generated around the primary coil and generates an induced electromotive force in the secondary coil of a receiving end, thereby transmitting power. Despite the advantage of excellent energy transmission efficiency, the electromagnetic induction scheme requires a short distance between the first coil and the second coil, and when an electronic device is not placed at a fixed location on the wireless power transmission device or the electronic device is not placed in a specific direction for charging, the charging efficiency may be reduced.

In addition to the electromagnetic induction method, there are other wireless charging technologies including a magnetic resonance method relying on the phenomenon of forming a magnetic field that vibrates at a specific resonant frequency in a transmitter coil and concentrating energy on a receiver coil that vibrates at the same resonant frequency, and an RF/microwave radiation method in which electrical energy is converted into electromagnetic waves and transmitted. Among them, the RF/microwave method is not currently applied as a wireless charging technology for electronic devices such as smartphones due to the risk of being harmful to the human body. Recently, the magnetic resonance method has been actively studied as a wireless charging technology to replace the electromagnetic induction method.

The above information is presented as background art only to assist with an understanding of the present disclosure. No determination has been made, and no assertion is made, as to whether any of the above might be applicable as prior art with regard to the disclosure.

### SUMMARY

According to an aspect of the disclosure, a wireless power transmission device includes: a first resonator including a first housing and a first coil inside the first housing, the first resonator being configured to wireless transmit power to an electronic device via magnetic resonance; and a second resonator including a second housing around at least a portion of the first housing, and a second coil inside the second housing, the second resonator being configured to wireless transmit power to the electronic device via the magnetic resonance, in a state in which the second resonator is coupled to the first resonator.

In a state in which the second resonator and the first resonator have a same resonant frequency while the first resonator is at least partially accommodated in a recess provided in the second resonator, the second resonator may be coupled to the first resonator.

The recess may include an opening, a groove, or a hole.

The first coil and the second coil may be configured to form magnetic fields at least partially in a same direction.

The first coil and the second coil may be disposed at least partially on the same plane.

The second coil may have a ring shape.

The first resonator may further include a first ferrite fixedly disposed in the first housing.

The second resonator may further include a second ferrite configured to have a variable position.

The second resonator may be configured to enable the second housing and the second coil to have variable shapes.

The first resonator may be connected to a power source, and the second resonator may be provided as an extended module substantially extending a first effective charging area by being coupled to the first resonator.

The first resonator may further include an impedance matching circuit and a first control circuit for controlling a frequency of the first coil.

The second resonator may further include a second control circuit configured to control a frequency of the second coil.

Each of the first resonator and the second resonator may further include at least one sensor configured to measure a transmission voltage or a transmission current.

At least a portion of the second housing of the second resonator may include a recess configured to accommodate the first housing of the first resonator, and at least another portion of the second housing supports the first housing to be at a predetermined height from a ground.

At least a portion of the second housing of the second resonator includes a recess for configured to accommodate the first housing of the first resonator, and at least another portion of the second housing is spaced apart from the first housing in a height direction by a predetermined distance.

According to one or more embodiments, a wireless power transmission device may be provided. The wireless power transmission device may include a first resonator including a first housing and a first coil disposed inside the first housing, and a second resonator including a second housing providing a space in which at least a portion of the first resonator is accommodable, and a second coil disposed inside the second housing and coupled to the first coil. The first resonator may provide a first effective charging area to an external device, and the second resonator may provide a second effective charging area to a second external electronic device, when coupled to the first resonator.

### BRIEF DESCRIPTION OF DRAWINGS

The above and other aspects, features, configurations, and advantages will be more apparent from the following detailed description taken in conjunction with the accompanying drawings, in which:

FIG. 1 illustrates a wireless power transmission device according to an embodiment.

FIG. 2 illustrates a wireless charging function implemented by a first resonator alone, while the first resonator is not accommodated in a recess of a second resonator according to an embodiment.

FIG. 3 illustrates a wireless charging function implemented by a first resonator and a second resonator together, while the first resonator is accommodated in a recess of the second resonator according to an embodiment.

FIG. 4 is a perspective view illustrating a wireless charging function implemented by a first resonator alone, while the first resonator is not accommodated in a recess of a second resonator according to an embodiment.

FIG. 5 is a perspective view illustrating a wireless charging function implemented by a first resonator and a second resonator together, while the first resonator is accommodated in a recess of the second resonator according to an embodiment.

FIG. 6 is a block diagram illustrating a wireless power transmission device according to an embodiment.

FIG. 7 illustrates a second resonator including a second ferrite at a variable position according to an embodiment.

FIG. 8 is a graph illustrating a simulation result of a ratio of a current flowing in a first coil and a current flowing in a second coil based on frequency control according to an embodiment.

FIG. 9 illustrates an equivalent circuit of a resonant circuit included in a first resonator and a resonant circuit included in a second resonator according to an embodiment.

FIG. 10 is a graph illustrating the intensity of the magnetic field at each position of a resonator according to a change in a relative ratio of a current flowing in a first coil and a current flowing in a second coil according to an embodiment.

FIG. 11 illustrates an exemplary use case of a wireless power transmission device according to an embodiment.

FIG. 12 illustrates an example of changing the shape of a coil in a wireless power transmission device according to an embodiment.

FIG. 13 illustrates a modification example of a wireless power transmission device according to an embodiment.

FIG. 14A is a perspective view illustrating a modification example of a wireless power transmission device according to an embodiment.

FIG. 14B is a front view illustrating a modification example of a wireless power transmission device according to an embodiment.

FIG. 15 illustrates a modification example of a wireless power transmission device according to an embodiment.

FIG. 16 illustrates a modification example of a wireless power transmission device according to an embodiment.

Throughout the attached drawings, similar reference numerals may be assigned to similar parts, components, and/or structures.

### DETAILED DESCRIPTION

Compared to an electromagnetic induction method, a magnetic resonance method as wireless charging technology for electronic devices such as smartphones has high alignment freedom between a transmitter coil and a receiver coil, and enables charging even when the coils are spaced apart from each other. However, although the magnetic resonance method is advantageous in terms of charging convenience compared to the electromagnetic induction method, the former does not have an effective charging distance long enough to have a significant difference from that in the latter in a commercialized product group.

For example, an electromagnetic induction-based wireless power transmission device among commercialized wireless power transmission devices is mainly a pad type or stand type in shape and provides a limited charging area accordingly. A magnetic resonance-based wireless power transmission device designed to replace the electromagnetic induction method is also mainly a pad type or stand type, thereby improving the charging convenience to some extent. However, since the magnetic resonance-based wireless power transmission device performs charging in a similar manner to the electromagnetic induction method, it has limitations in providing a new charging experience to a user.

According to an embodiment of the disclosure, a wireless power transmission device may be provided, which when charging a plurality of electronic devices, may supply wireless power to the plurality of electronic devices omnidirectionally, and enable them to be charged even when they are not placed in a specified area.

According to an embodiment of the disclosure, a wireless power transmission device may be provided, which is capable of charging an electronic device regardless of its location and positional orientation as long as it is within a specified distance from the wireless power transmission device.

According to an embodiment of the disclosure, a wireless power transmission device may be provided, which includes a resonator used to extend a transmission radius of wireless power.

According to an embodiment of the disclosure, a new charging experience may be provided to a user using a wireless power transmission device.

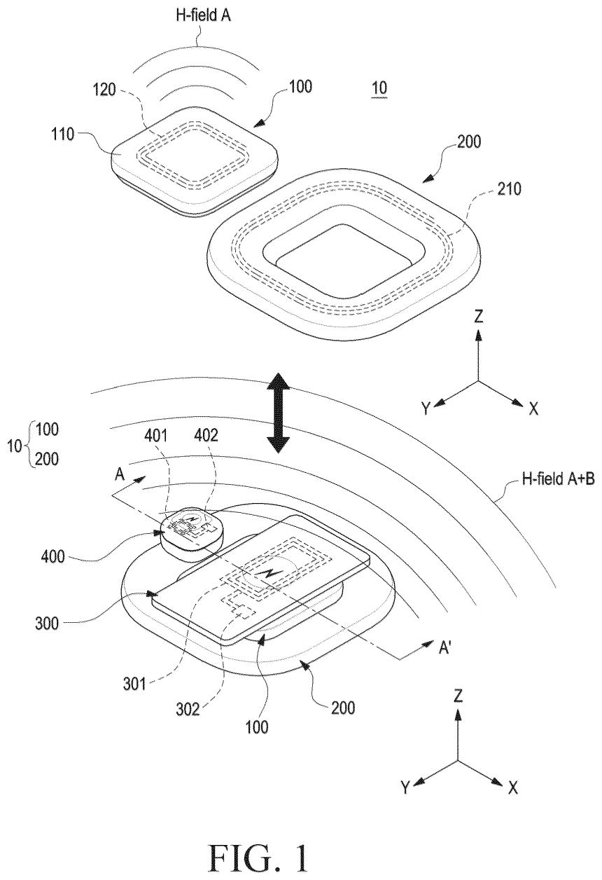

With reference to the embodiments of FIGS. 1 to 16, a wireless power transmission device 10 and/or wireless power reception devices 300 and 400 (hereinafter, referred to as ‘electronic devices 300 and 400’) according to various embodiments of the disclosure will be described below in detail.

In the following detailed description of FIG. 1, a longitudinal direction of the wireless power transmission device 10 and/or the electronic devices 300 and 400 may be defined as a ‘Y-axis direction’, a width direction as an ‘X-axis direction’, and/or a height direction (thickness direction) as a ‘Z-axis direction’. In the following detailed description, the references to the longitudinal direction, the width direction, and/or the height direction (or thickness direction) may indicate the longitudinal direction, the width direction, and/or the height direction (or thickness direction) of the wireless power transmission device 10 and/or the electronic devices 300 and 400. In some embodiments, regarding a direction in which a component is oriented, ‘negative/positive −/+’ may be mentioned together with the Cartesian coordinate system illustrated in the drawings. According to an embodiment, a height-direction arrangement relationship of a component or another component, that is, a reference for up/down, may follow the Z-axis direction. That is, when a component is disposed above another component, it may mean that the component is disposed at a higher position in the Z-axis direction than the other component, and when a component is disposed below another component, it may mean that the component is disposed at a lower position in the Z-axis direction than the other component. Meanwhile, it should be noted that even if a component is disposed above or below another component, it does not mean that the entire component is located above or below the entirety of the other component. For example, although a portion of a component may be disposed above a portion of another component, another portion of the component may be disposed below another portion of the other component. In the following description, when it is said that a component is overlapped or stacked with another component, it should be noted that the above description of a height-direction arrangement relationship may be applied. This is based on the Cartesian coordinate system illustrated in the drawings, for conciseness of the description, and it should be noted that the description of such directions or components does not limit one or more embodiments of the disclosure.

FIG. 1 illustrates the wireless power transmission device 10 according to an embodiment.

The wireless power transmission device 10 may wirelessly transmit power to the electronic device 300 and/or electronic device 400.

According to one or more embodiments of the disclosure, the wireless power transmission device 10 may transmit power according to a magnetic resonance method. According to one or more embodiments, the wireless power transmission device 10 may be implemented in a manner defined in the A4WP Alliance for Wireless Power standard (or the Air Fuel Alliance (AFA) standard). The wireless power transmission device 10 may include a coil capable of generating a time-varying magnetic field with a magnitude changing over time, when an AC current flows according to the resonance method. A process in which the wireless power transmission device 10 generates a magnetic field may be expressed as ‘the wireless power transmission device 10 outputs power’ or ‘wirelessly transmits power’. Further, the electronic devices 300 and 400 may include a coil in which an induced electromotive force is generated by a magnetic field with a magnitude changing over time formed in the surroundings. A process in which the electronic device 300 and 400 generate an induced electromotive force through the coil may be expressed as ‘power is input to the electronic devices 300 and 400’ or ‘the electronic devices 300 and 400 wirelessly receive power’. A process in which the wireless power transmission device 10 wirelessly transmits power and the electronic devices 300 and 400 wirelessly receive power may be expressed as ‘power is transmitted from the wireless power transmission device 10 to the electronic devices 300 and 400’.

The wireless power transmission device 10 may include a first resonator 100 and a second resonator 200. The first resonator 100 may be a component that may wirelessly transmit power by itself, and the second resonator 200 may be a component that may wirelessly transmit power, when coupled to the first resonator 100. When the wireless power transmission device 10 wirelessly transmits power to the electronic devices 300 and 400, the first resonator 100 may operate as a base module that provides a wireless power transmission function within a specified charging area, and the second resonator 200 may operate as an extended module that substantially extends the wireless charging area of the first resonator 100.

Even when the first resonator 100 is not coupled to the second resonator 200, the first resonator 100 may perform the wireless power transmission function. On the other hand, when the second resonator 200 is not coupled to the first resonator 100, the second resonator 200 may not perform the wireless power transmission function. Referring to FIG. 1 as an example, when the first resonator 100 and the second resonator 200 are separated from each other, only the first resonator 100 is shown as performing the wireless power transmission function. Implementation of the wireless power transmission function only in the first resonator 100 is shown in FIG. 1 as a magnetic field H-field A in a simplified manner.

The first resonator 100 may include a first housing 110 and a first coil 120. The first coil 120 may be disposed inside the first housing 110. The first resonator 100 may further include at least one capacitor. According to embodiments, the first coil 120 may include a plurality of coils, and each of the at least one capacitor may include a plurality of capacitors. The first coil 120 may form a resonant circuit together with the at least one capacitor. The first coil 120 may be coupled to the at least one capacitor and vibrate at a specified resonant frequency f. For example, when the electronic devices 300 and 400 are located within an effective charging distance of the first resonator 100 including the first coil 120 vibrating at the specified resonant frequency f, and the coils included in the electronic device 300 and 400 resonate together at the specified resonant frequency f, power may be transferred from the first resonator 100 to the electronic devices 300 and 400.

The first resonator 100 may further include a power source, a DC-AC conversion circuit, an amplifier circuit, and/or an impedance matching circuit. In an embodiment, the power source, the DC-AC conversion circuit, the amplifier circuit, and/or the impedance matching circuit may be disposed inside the first housing 110. In an embodiment, the power source may be a component which is connected to the first resonator 100 outside the first housing 110 and supplies power to the first resonator 100.

In an embodiment, the first resonator 100 may transmit power to the electronic devices 300 and 400 using an electromagnetic induction method in addition to the magnetic resonance method. For example, the first resonator 100 may further include at least one coil in addition to the first coil 120 for implementing the resonance method. The first resonator 100 may also perform power transfer to the electronic devices 300 and 400 by electromagnetic induction, using the additional at least one coil. Herein, the first resonator 100 may implement electromagnetic induction in a manner defined in the Wireless Power Consortium (WPC) standard (or the Qi standard). According to an embodiment, for implementing electromagnetic induction, the first resonator 100 may further include at least one coil in addition to the at least one coil and configure a circuit for electromagnetic induction. As the first resonator 100 is configured to enable wireless power transmission to the electronic devices 300 and 400 by electromagnetic induction when needed, it may increase the charging efficiency of the electronic devices 300 and 400. However, it should be noted that the following description focuses on the magnetic resonance method excluding the electromagnetic induction method.

The second resonator 200 may include a second housing 210 and a second coil 220. The second coil 220 may be disposed inside the second housing 210. The second resonator 200 may further include at least one capacitor. According to an embodiment, the second coil 220 may include a plurality of coils, and each of the at least one capacitor may include a plurality of capacitors. The second coil 220 may form a resonant circuit with the at least one capacitor. The second coil 220 may be coupled to the at least one capacitor and vibrate at the frequency f that is the same as the resonant frequency f of the first coil 120 and the at least one capacitor coupled to the first coil 120.

The second resonator 200 may be configured to operate as a resonator only when coupled to the first resonator 100. A condition of a ‘coupling’ between the first resonator 100 and the second resonator 200, which allows the second resonator 200 to operate as a resonator, may include a case where the first resonator 100 is at least partially accommodated in a recess provided in the second resonator 200 and has the same resonant frequency, as illustrated in FIG. 1. In addition to the above condition, the condition of ‘coupling’ between the first resonator 100 and the second resonator 200, which allows the second resonator 200 to operate as a resonator, may also include a case where the first coil 120 of the first resonator 100 and the second coil 220 of the second resonator 200 are configured to form magnetic fields in the same direction. In addition to the aforementioned conditions, the condition of ‘coupling’ between the first resonator 100 and the second resonator 200, which allows the second resonator 200 to operate as a resonator, may include a case where the first coil 120 and the second coil 220 are arranged at least partially on the same plane.

According to an embodiment, the second resonator 200 may include a recess having a diameter substantially corresponding to the diameter of the first housing 110 of the first resonator 100. For example, when the first resonator 100 is fitted into the recess of the second resonator 200, coupling between the first resonator 100 and the second resonator 200 may be achieved.

Referring to FIG. 1, the second housing 210 of the second resonator 200 may be approximately formed in a ring shape. In addition, the second coil 220 of the second resonator 200 may also have a ring shape corresponding to the shape of the second housing 210. Accordingly, while the first resonator 100 is at least partially accommodated in the recess of the second resonator 200, the second coil 220 may surround most of the first coil 120 of the first resonator 100. When the first coil 120 of the first resonator 100 resonates at the specified frequency f while the first resonator 100 is at least partially accommodated in the recess of the second resonator 200, the second coil 220 of the second resonator 200 may also be configured to resonate at the same frequency f. Unlike the case where the wireless power transmission function is implemented only in the first resonator 100, the wireless power transmission function is implemented in the first resonator 100 and the second resonator 200 coupled to the first resonator 100, so that a wider magnetic field H-field A+B may be formed.

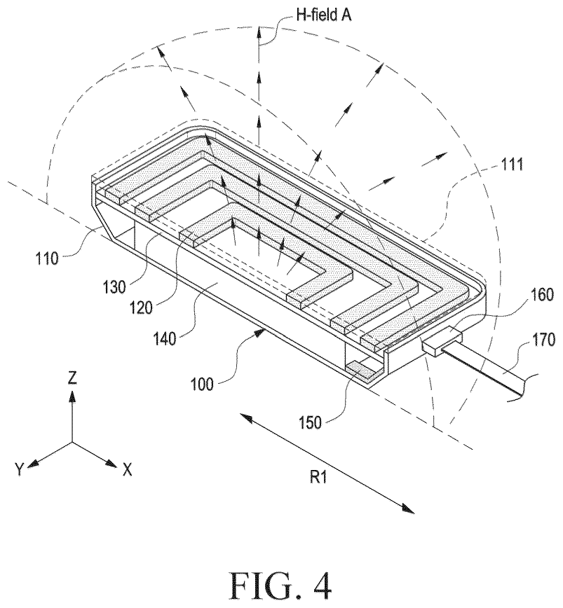

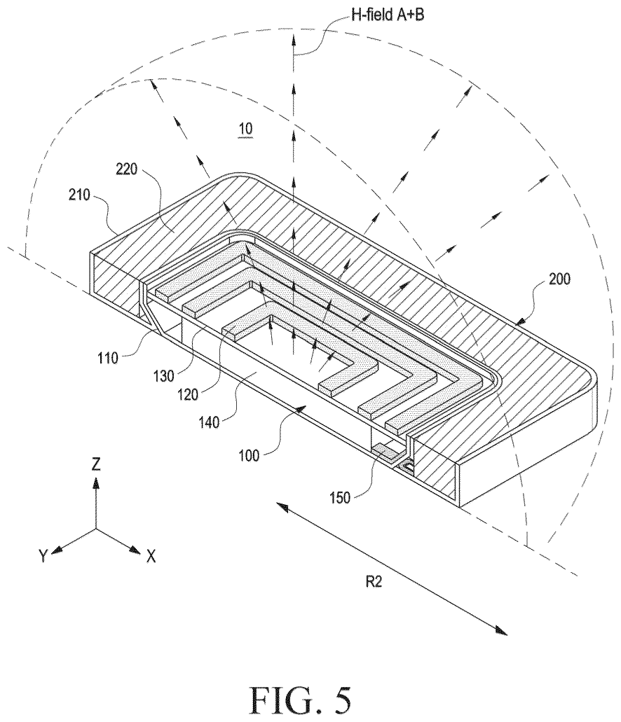

As illustrated in FIG. 1, according to an embodiment, a plurality of electronic devices may be placed on the wireless power transmission device 10. According to an embodiment, a plurality of electronic devices may be freely placed around the wireless power transmission device 10. For example, a smartphone-type electronic device 300 and a wearable-type electronic device 400 may be placed together on the wireless power transmission device 10. Each of the electronic devices 300 and 400 may be provided with a resonant circuit including at least one coil 301 and/or 401 and at least one capacitor 302 and/or 402. Each of these electronic devices 300 and 400 may be coupled to the first coil 120 of the first resonator 100 of the wireless power transmission device 10 and/or the second coil 220 of the second resonator 200 at the same frequency, and receive power wirelessly. Compared to the case where the wireless power transmission device 10 performs a wireless charging operation using the electromagnetic induction method, when the wireless charging operation is performed using the magnetic resonance method as in the disclosure, high charging efficiency may be achieved even when each of the electronic devices 300 and 400 is not precisely aligned with respect to the first resonator 100 and/or the second resonator 200. Further, compared to the case where only the first resonator 100 forms a magnetic field, when the first resonator 100 and the second resonator 200 are simultaneously used to form a magnetic field, a longer effective charging distance (or a wider effective charging area) may be secured. For example, the first resonator 100 may provide a first effective charging distance (e.g., R1 of FIG. 4 described below) to the electronic devices 300 and 400, and the second resonator 200 may provide a second effective charging distance (e.g., R2 of FIG. 5 described below) to the electronic device 300, 400, which is longer than the first effective charging distance (e.g., R1 of FIG. 4 described below), when coupled to the first resonator 100. In another example, the first resonator 100 may provide a first effective charging area H-field A to the electronic devices 300 and 400, and the second resonator 200 may provide a second effective charging area H-field B wider than the first effective charging area H-field A to the electronic devices 300 and 400, when coupled to the first resonator 100. The ‘effective charging distance’ or ‘effective charging area’ may mean a distance or area that allows the electronic devices 300 and 400 to be charged to a specified charging percent within a specified time.

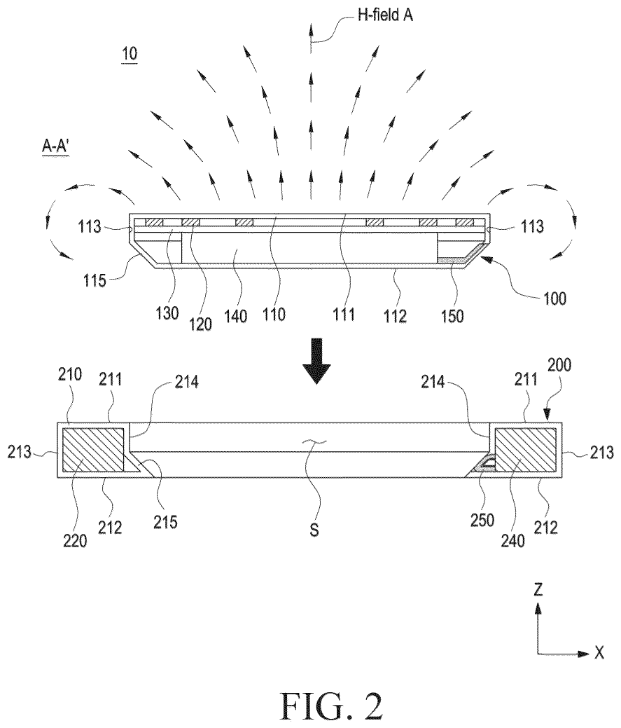

The components of the wireless power transmission device 10 will be described in more detail with reference to FIG. 2 and the following drawings. In the following drawings, the at least one coil 301 and 302 and the at least one capacitor 302 and 402 included in the electronic devices 300 and 400 may be omitted for convenience of description.

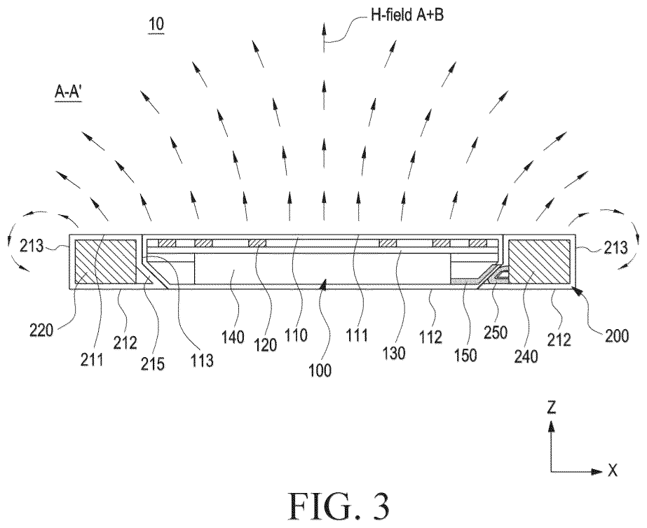

FIG. 2 illustrates the wireless charging function implemented by the first resonator 100, when the first resonator 100 is not accommodated in a recess of the second resonator 200 according to an exemplary embodiment. FIG. 3 illustrates the wireless charging function implemented by the first resonator 100 and the second resonator 200 together, when the first resonator 100 is accommodated in the recess s of the second resonator 200 according to an exemplary embodiment.

FIGS. 2 and 3 may illustrate cross-sections of the wireless power transmission device 10, taken along a direction A-A′ in FIG. 1 according to an exemplary embodiment.

The first resonator 100 may include the first housing 110 and the first coil 120 disposed inside the first housing 110. The first housing 110 may provide a space for accommodating the first coil 120 and predetermined electronic component(s) 140 therein. The first housing 110 may include a top member 111 forming a top surface of the first resonator 100, a bottom member 112 forming a bottom surface of the first resonator 100, and a side member 113 surrounding a space between the top member 111 and the bottom member 112 and forming a side surface. According to an embodiment, the first coil 120 may be disposed at a position adjacent to the top member 111 and face the top member 111. According to an exemplary embodiment, when the first resonator 100 is disposed on a flat surface such as the ground or a desk, a magnetic field formed at the center of the first coil 120 may be directed in the height direction (Z-axis direction). According to an embodiment, the first resonator 100 may further include a ferrite 130. According to an embodiment, the ferrite 130 included in the first resonator 100 may be disposed on a rear surface of the first coil 120 and at a fixed position. The first resonator 100 may further include a first connecting member 150 for connecting the electronic component 140 disposed inside the first resonator 100 to an external source (e.g., the second resonator 200).

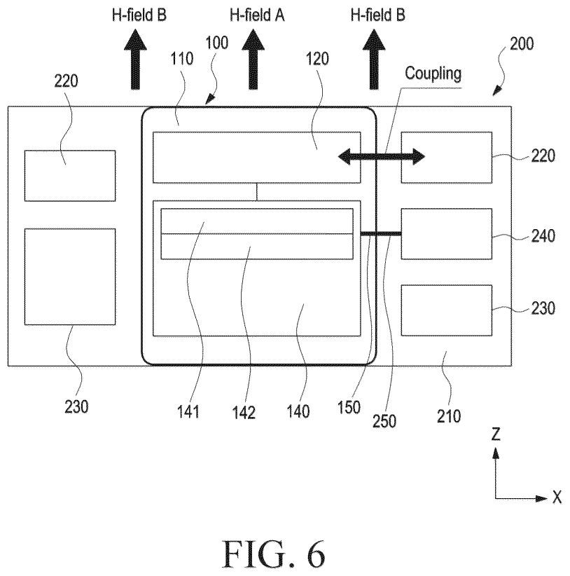

The second resonator 200 may include the second housing 210 and the second coil 220 disposed inside the second housing 210. The second housing 210 may provide a space for accommodating the second coil 220 and second predetermined electronic component(s) 240 therein. The second housing 210 may have a ring shape. The second housing 210 may include a top member 211 forming a top surface of the second resonator 200, a bottom member 212 forming a bottom surface of the second resonator 200, and a second side member 213 surrounding a space between the top member 211 and the bottom member 212 and forming a side surface. The recess included in the second resonator 200 may be formed by the second housing 210, and may be a concept including an opening, a groove, or a hole. The second housing 210 may further include an inner side surface 214 for forming the recess. According to an exemplary embodiment, a mounting portion 215 for mounting the first housing 110 thereon may be formed in the second housing 210, and an inclined portion 115 may be formed to correspond to the mounting portion 215 in the first housing 110. According to an embodiment, the second coil 220 may be formed as a ring-shaped coil corresponding to the shape of the second housing 210. The second coil 220 may be disposed at a position adjacent to the top member 211 and/or the bottom member 212, and face the top member 211 and/or the bottom member 212. According to an embodiment, when the second resonator 200 is placed on a flat surface such as the ground or a desk, a magnetic field formed at the center of the second coil 220 may be directed in the height direction (Z-axis direction). The second resonator 200 may further include a second ferrite 230, as illustrated on FIG. 6. The second ferrite 230 included in the second resonator 200 may be configured to have a variable position. The second resonator 200 may further include a second connecting member 250 for connecting the second electronic component 240 disposed inside the second resonator 200 to the outside (e.g., the first resonator 100).

Referring to FIGS. 2 and 3, the ‘Arrows’ may illustrate magnetic lines of force associated with magnetic fields (e.g., H-fields) generated from the resonant circuits, based on the flow of a clockwise current (e.g., AC current) in the resonant circuit of the first resonator 100 including the first coil 120 and/or the resonant circuit of the second resonator 200 including the second coil 220, when the wireless power transmission device 10 is viewed from one direction parallel to the Y axis.

It may be identified that more magnetic lines of force are formed when the first resonator 100 and the second resonator 200 implement the wireless charging function together while the first resonator 100 is accommodated in the recess of the second resonator 200 than when the first resonator 100 alone implements the wireless charging function while the first resonator 100 is not accommodated in the recess of the second resonator 200. This may indicate that the area of the magnetic field H-field A+B formed when the first resonator 100 and the second resonator 200 implement the wireless charging function together while the first resonator 100 is accommodated in the recess of the second resonator 200 is larger than the area of the magnetic field H-field A formed when the first resonator 100 alone implements the wireless charging function together while the first resonator 100 is not accommodated in the recess of the second resonator 200.

While the first resonator 100 is accommodated in the recess of the second resonator 200, the first connecting member 150 and the second connecting member 250 may contact. The contact may include not only a physical direct connection between one component and another component, but also an electrical connection between the one component and the other component while being spaced apart by a predetermined distance. The first resonator 100 and the second resonator 200 may communicate data through the first connecting member 150 and the second connecting member 250. The data may be, for example, data for controlling a first control circuit 142 and a second control circuit to adjust the inductance of the first coil 120, the inductance of the second coil 220, or the capacitance of the capacitors. According to an embodiment, the first resonator 100 and the second resonator 200 may include distance communication modules (e.g., Bluetooth low energy (BLE)) additionally or alternatively to the first connecting member 150 and the second connecting member 250 provided therein, respectively, to communicate data.

FIG. 4 is a perspective view illustrating the wireless charging function implemented by the first resonator 100 alone, when the first resonator 100 is not accommodated in the recess of the second resonator 200 according to an exemplary embodiment. FIG. 5 is a perspective view illustrating the wireless charging function implemented by the first resonator 100 and the second resonator 200 together, when the first resonator 100 is accommodated in the recess of the second resonator 200 according to an exemplary embodiment.

FIGS. 4 and 5 may be perspective views illustrating cross-sections of the first resonator 100 and/or the second resonator 200, taken along the direction A-A′ in FIG. 1.

Referring to FIG. 4, the first resonator 100 may perform the wireless power transmission function for the electronic devices 300 and 400 on its own. According to an embodiment, the first resonator 100 may receive power from an external power source. In the embodiment illustrated in FIG. 4, a connector 170 and a connector terminal 160 are shown as connected to the first resonator 100 to receive power from an external power source.

FIG. 4 illustrates an example of the first coil 120 adjacent to the top member 111 of the first resonator 100. The first coil 120 may include a coil wound a plurality of times. When a clockwise current (e.g., AC current) flows through the first coil 120 disposed parallel to a xy plane, magnetic force lines passing through the center of the first coil 120 may be directed in the height direction (Z-axis direction) of the first resonator 100, and the magnetic field H-field A may be formed to spread approximately radially around it. The effective charging distance of the wireless power transmission device 10 formed by the first resonator 100 may be denoted by R1.

Referring to FIGS. 4 and 5, the first coil 120 included in the first resonator 100 and the second coil 220 included in the second resonator 200 may have the same or similar shapes, but may also have different shapes. For example, the first coil 120 and/or the second coil 220 may include a coil wound a plurality of times, or may be applied in various forms, such as a form in which a plurality of ring-shaped coils are stacked in the height direction of the wireless power transmission device 10.

Referring to FIG. 5, the first coil 120 and the second coil 220 may be coupled at the same frequency, and when the clockwise current (e.g., AC current) flows through the first coil 120 and the second coil 220 disposed parallel to the xy plane, magnetic force lines passing through the centers of the first coil 120 and the second coil 220 may be directed in the height direction (Z-axis direction) of the first resonator 100 and the second resonator 200, and the magnetic field H-field A+B may be formed to spread approximately radially around the first coil 120 and the second resonator 200. The effective charging distance of the wireless power transmission device 10 formed by the first resonator 100 and the second resonator 200 may be denoted by R2, which is greater than the effective charging distance of the wireless power transmission device 10 formed only by the first resonator 100.

The wireless power transmission device 10 may be understood as a concept in which the first resonator 100 provides the first effective charging area to the electronic devices 300 and 400, and the second resonator 200 provides the second effective charging area to the electronic devices 300 and 400, when coupled to the first resonator 100. The first effective charging area and the second effective charging area may overlap at least partially.

FIG. 6 is a block diagram illustrating the wireless power transmission device 10 according to an embodiment.

Referring to FIG. 6, components included in the wireless power transmission device 10 may be described in more detail. A description redundant to the foregoing embodiments described with reference to FIGS. 1 to 5 will be avoided below.

Referring to FIG. 6, the first resonator 100 may include, as the electronic component 140, a power supply system that supplies a current to the first coil 120 to form the magnetic field H-field through the resonant circuit including the first coil 120. The supply system may include, for example, an impedance matching circuit 141 and/or a first control circuit 142. According to an embodiment, the supply system may further include an amplifier circuit. The first control circuit 142 may be configured to control a resonant frequency in order to supply a current to the first coil 120. For example, the first control circuit 142 may control the resonant frequency by controlling the inductance of the first coil 120 or the capacitance of the capacitor, thereby allowing a current of a predetermined magnitude to flow along the first coil 120 in a predetermined direction (e.g., clockwise or counterclockwise).

The second resonator 200 may include a second control circuit as the second electronic component 240. According to an embodiment, the second coil 220 may be mutually coupled to the first coil 120 and indirectly receive a current. The second control circuit may be configured to control a resonant frequency in order to control the current supplied to the second coil 220. For example, the second control circuit may control a resonant frequency by controlling the inductance of the second coil 220 or the capacitance of the capacitor, thereby allowing a current of a predetermined magnitude to flow along the second coil 220 in a predetermined direction (e.g., clockwise or counterclockwise).

The impedance matching circuit 141 of the first resonator 100 may change at least one of the inductance, capacitance, or reactance of the circuit so that the first coil 120 and the second coil 220 may be impedance-matched by considering a charging situation. It may be necessary to control the magnetic field H-field A or H-field B from the first resonator 100 and/or the second resonator 200 according to various charging situations such as the number of the electronic devices 300 and 400 disposed around the wireless power transmission device 10, the positions of the electronic devices 300 and 400, and an intended charging amount. In consideration of the various charging situations, the first control circuit 142 and the second control circuit may be controlled respectively through the impedance matching circuit 141.

According to an embodiment, the first resonator 100 and the second resonator 200 may include the ferrites (e.g., first ferrite 130 and second ferrite 230), respectively. The first ferrite 130 of the first resonator 100 may have a fixed position, and the second ferrite 230 of the second resonator 200 may have a variable position. According to an embodiment, the inductance may be controlled by changing the position of the second ferrite 230.

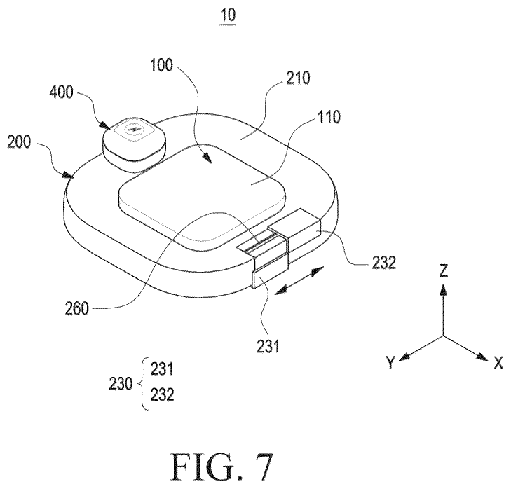

FIG. 7 illustrates the second resonator 200 including the second ferrite 230 having a variable position according to an embodiment.

According to an embodiment, the second ferrite 230 may be disposed inside the second housing 210 of the second resonator 200, but may also be disposed outside the second housing 210 as illustrated in FIG. 7. According to an embodiment illustrated in FIG. 7, the second housing 210 may be provided with a predetermined rail structure 260. Further, the second ferrite 230 may include a first part 231 having a fixed position with respect to the second housing 210, and a second part 232 having a variable position with respect to the second housing 210. The second part 232 may be guided by the predetermined rail structure 260 to slide along one direction (e.g., the longitudinal direction (Y-axis direction)) of the wireless power transmission device 10. The second part 232 may be formed to be reciprocally movable under the guidance of the predetermined rail structure 260, thereby changing the inductance of the second resonator 200.

However, the embodiment illustrated in FIG. 7 is only one of various examples of changing impedance, and it should be noted that the ferrite and rail structure for implementing this are also only one of various examples, not limiting the scope of the disclosure.

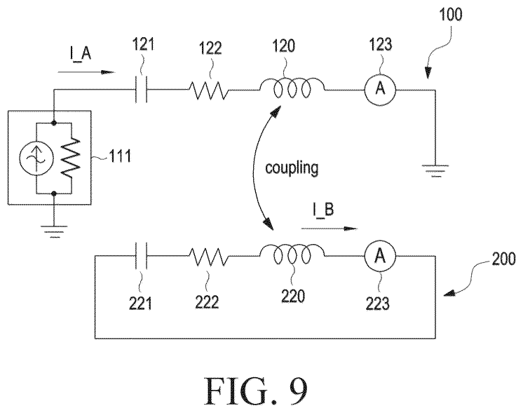

FIG. 9 illustrates an exemplary embodiment of a circuit of the resonant circuit included in the first resonator 100 and the resonant circuit included in the second resonator 200 according to an embodiment.

Referring to FIG. 9, the first resonator 100 may form a resonant circuit by including the first coil 120, at least one capacitor 121, and a resistance element 122. The second resonator 200 may form a resonant circuit including the second coil 220, at least one capacitor 221, and a resistance element 222. Power may be supplied from a power source 116 to the resonant circuit of the first resonator 100, and a current I_A corresponding to an impedance, which is set in consideration of the magnitude of the power supplied from the power source 116, the inductance of the first coil 120, the capacitance of the capacitor 121, the reactance of the resistance element 122, and various charging environments for the electronic devices 300 and 400, may flow in the resonant circuit of the first resonator 100.

A current I_B corresponding to an impedance, which is set in consideration of the magnitude of an electromotive force induced in the second coil 220 through coupling to the first coil 120, the inductance of the second coil 220, the capacitance of the at least one capacitor 221, the reactance of the resistance element 222, and various charging environments for the electronic devices 300 and 400 may flow in the resonant circuit of the second resonator 200.

The resonant circuit of the first resonator 100 may further include the impedance matching circuit 141, and the impedance matching circuit 141 of the first resonator 100 may change at least one of the inductance, capacitance, or reactance of the circuit in consideration of a charging situation, so that the first coil 120 and the second coil 220 are impedance-matched. This allows the current I_A flowing in the first coil 120 and the current I_B flowing in the second coil 220 to be controlled.

When the magnitude of the power provided from the power source 116 is constant, the sum of the magnitude of power output from the first resonator 100 and the magnitude of power output from the second resonator 200 may be constant. According to an embodiment, the magnitude of the current I_A flowing in the first coil 120 and the magnitude of the current I_B flowing in the second coil 220 may be proportional to the magnitude of the power output from the first resonator 100 and the magnitude of the power output from the second resonator 200.

The wireless power transmission device 10 may further include at least one sensor 123 in the first resonator 100 and at least one sensor 223 in the second resonator 200. The at least one sensor 123 may be configured to measure the magnitude of the current I_A of the first coil, and the at least one sensor 223 may be configured to measure the magnitude of the current I_B of the second coil 220.

The at least one sensor 123 and 223 may be sensors that measure the voltages and currents of the first resonator 100 and the second resonator 200 included in the wireless power transmission device 10. The wireless power transmission device 10 may measure output impedances of power amplifiers and/or input impedances of the resonant circuits through the at least one sensor 123 and/or 223. For example, power consumption may be monitored by measuring a transmission voltage V TX_IN and a transmission current I TX_IN using the at least one sensor 123 and 223, and through this, a change in the input impedances of the resonant circuits may be detected. When the impedance changes are detected, whether the electronic devices 300 and/or 400 receiving wireless power are placed/removed, whether a foreign substance is detected, and a change in the amount of received power may be identified. For example, when one of the electronic devices 300 and 400 moves and becomes closer to the wireless power transmission device 10 during charging of the plurality of electronic devices 300 and 400 in the wireless power transmission device 10, the reception power and efficiency of the other electronic device may decrease. The power supply system 140 of the first resonator 100 may control the transmission and efficiency of wireless power to the plurality of electronic devices 300 and 400 according to a predetermined algorithm or a command input from a user, considering a detected impedance change.

Although not separately illustrated in the drawings, the electronic devices 300 and 400 may also include at least one sensor. For example, the electronic device 300 and 400 may detect the movement of the electronic devices 300 and 400 by themselves through the at least one sensor (e.g., motion sensor). The motion sensor for detecting the movement may include, for example, at least one of a gyro sensor, an acceleration sensor, an angular velocity sensor, a gravity sensor, a geomagnetic sensor, or an infrared sensor. However, the type of the sensor is not limited thereto. For example, the electronic devices 300 and 400 may measure a voltage V_{RECT} output from a rectifier circuit using the at least one sensor. A change in positional relationships between the electronic devices 300 and 400 and the wireless power transmission device 10 (whether they are closer to or farther from the resonators) may be identified based on the measured output voltage V_{RECT}. Data sensed through the at least one sensor may be provided to processors of the electronic devices 300 and 400, and then provided to the wireless power transmission device 10 through a short-range communication module (e.g., BLE). In summary, the wireless power transmission device 10 may control the transmission and efficiency of wireless power to the plurality of electronic devices 300 and 400 by using data detected from the at least one sensor 123 and 223 and/or the at least one sensor included in the electronic devices 300 and 400.

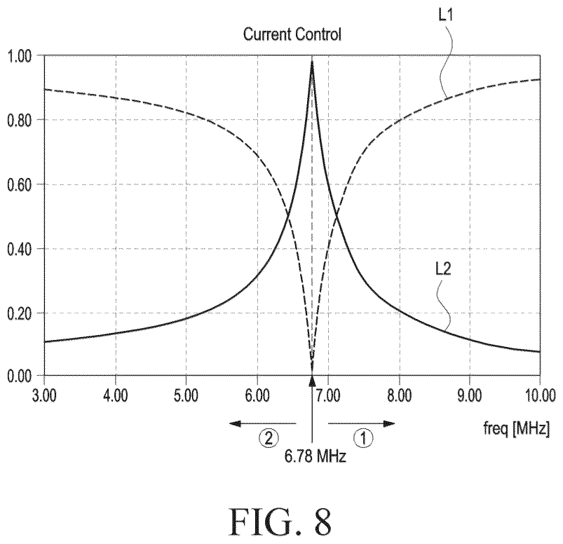

FIG. 8 is a graph illustrating a simulation result of a ratio of the current I_A flowing in the first coil 120 and the current I_B flowing in the second coil 220 based on frequency control according to an embodiment.

Referring to FIG. 8, a dotted-line graph L1 illustrates the magnitude of the current I_A flowing in the first coil 120 relative to the sum of the current I_A flowing in the first coil 120 and the current I_B flowing in the second coil 220. A solid-line graph L2 illustrates the magnitude of the current I_B flowing in the second coil 220 relative to the sum of the current I_A flowing in the first coil 120 and the current I_B flowing in the second coil 220.

In the graphs of FIG. 9, when the resonant frequency is a specific value (e.g., 6.78 MHz), the magnitude of the current I_B flowing in the second coil 220 may be largest (e.g., 0.98), and the magnitude of the current I_A flowing in the first coil 120 may be smallest (e.g., 0.02). When the frequency changes from the specific value in a frequency-increasing direction (e.g., an arrowed direction \textcircled{1}), the magnitude of the current I_A flowing in the first coil 120 and the magnitude of the current I_B flowing in the second coil 220 may change, while the current I_A flowing in the first coil 120 and the current I_B flowing in the second coil 220 are directed in the same direction. When the frequency changes from the specific value in a frequency-decreasing direction (e.g., an arrowed direction \textcircled{2}), the magnitude of the current I_A flowing in the first coil 120 and the magnitude of the current I_B flowing in the second coil 220 may change, while the current I_A flowing in the first coil 120 and the current I_B flowing in the second coil 220 are directed in different directions. When the frequency gradually increases from a specified resonant frequency, a magnetic field formed by the currents flowing through the first coil 120 and the second coil 220 may be strengthened (or a magnetic field area may be extended). When the frequency gradually decreases from the specified resonant frequency, the magnetic field formed by the currents flowing through the first coil 120 and the second coil 220 may be attenuated (or the magnetic field area may be reduced). According to an embodiment, as a condition of ‘coupling’ between the first resonator 100 and the second resonator 200, the first coil 120 of the first resonator 100 and the second coil 220 of the second resonator 200 may be made to form magnetic fields in the same direction, while having a large frequency range based on the specified resonant frequency (e.g., 6.78 MHz), thereby strengthening the magnetic field.

According to an embodiment of the disclosure, the first coil 120 and the second coil 220 may be impedance-matched by controlling a frequency flowing through each of them, and may be controlled to have frequencies greater than the resonant frequency so that the magnetic field is strengthened (or the magnetic field area is extended).

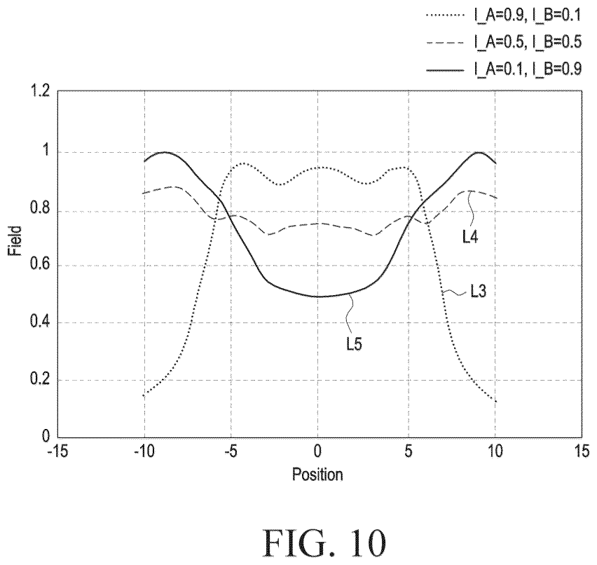

FIG. 10 is a graph illustrating the intensity of a magnetic field at each position of a resonator according to a change in a relative ratio of the current I_A flowing through the first coil 120 and the current I_B flowing through the second coil 220 according to an exemplary embodiment.

In FIG. 10, the position of a resonator may mean the position of the resonator on the line A-A′ in FIG. 1, and when the first resonator 100 is accommodated in the recess of the second resonator 200, the center of the first resonator 100 may be referred to as position 0. Position 0 may be a reference position for the effective charging distance (or effective charging area) of the resonator.

On the assumption that the sum of the magnitudes of the current I_A flowing in the first coil 120 and the current I_B flowing in the second coil 220 is 1, when the ratio of the current I_A flowing in the first coil 120 and the current I_B flowing in the second coil 220 is 9:1, a convex hat-shaped magnetic field H-field may be formed centered on position 0 which is the center of the first resonator 100, as illustrated in a third graph L3. For example, when the magnetic field has a maximum value of 1 and a minimum value of 0, a large magnetic field close to 1 may be formed at positions −5 to 5, and a magnetic field may be formed at distances or areas outside of positions −5 to 5 in a form that converges to 0 as the distance increases. This may mean that the magnitude of power output from the first resonator 100 is large and the magnitude of power output from the second resonator 200 is significantly small.

On the assumption that the sum of the current I_A flowing in the first coil 120 and the current I_B flowing in the second coil 220 is 1, when the ratio of the current I_A flowing in the first coil 120 and the current I_B flowing in the second coil 220 is 1:1, a uniform magnetic field H-field may be formed with an intensity of approximately 0.8 within the effective charging distance (or effective charging area), as illustrated in a fourth graph L4.

On the assumption that the sum of the current I_A flowing in the first coil 120 and the current I_B flowing in the second coil 220 is 1, when the ratio of the current I_A flowing in the first coil 120 and the current I_B flowing in the second coil 220 is 1:9, a magnetic field H-field in the shape of a concave inverted hat may be formed, as illustrated in a fifth graph L5. For example, when the magnetic field has a maximum value of 1 and a minimum value of 0, a magnetic field of 0.8 or less may be formed at positions −5 to 5 and have a minimum value at position 0, and a magnetic field may be formed at distances or areas outside of positions −5 to 5 in a form closer to 1 as the distance increases. This may mean that the magnitude of power output from the second resonator 200 is large, and the magnitude of power output from the first resonator 100 is significantly small.

Referring to FIGS. 8 to 10 together, the wireless power transmission device 10 may perform the wireless power transmission function by coupling the first resonator 100 and the second resonator 200, thereby extending the effective charging distance (or effective charging area) of the magnetic field. Meanwhile, the wireless power transmission device 10 of the disclosure may provide an optimal charging environment in response to various charging situations by controlling the magnitudes and/or directions of the current I_A flowing in the first resonator 100 and the current I_B flowing in the second resonator 200.

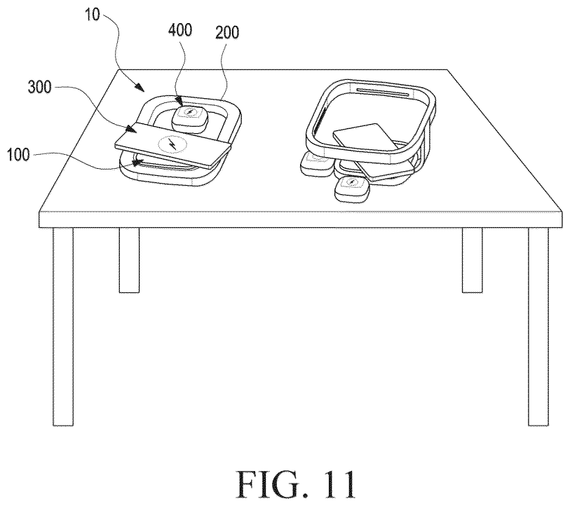

FIG. 11 illustrates an exemplary use case of the wireless power transmission device 10 according to an embodiment.

The wireless power transmission device 10 may be configured to enable wireless charging for at least one electronic device 300 and 400 in various environments such as the ground and a desk. A plurality of electronic devices 300 and 400 may be provided and placed on top of the wireless power transmission device 10 or at any location around the wireless power transmission device 10.

The wireless power transmission device 10 may perform wireless charging for the electronic devices 300 and 400 placed within a specified effective charging distance (or effective charging area).

According to an embodiment, the electronic devices 300 and 400 may include displays that may visually provide various pieces of information including charging information to a user. According to an embodiment, each of the displays may be formed to occupy most of the area of one surface of the electronic device 300 or 400 to provide a wide screen. According to an embodiment, the electronic devices 300 and 400 may provide information about whether wireless power is received or information such as time, temperature, and humidity through the displays. According to an embodiment, the displays may further include touch circuits or pressure sensors that may measure the intensity of pressure for a touch.

According to an embodiment, in the wireless power transmission device 10, the second housing 210 of the second resonator 200 may have various shapes that are different from that in the above-described embodiment (e.g., the embodiment of FIGS. 1 to 5 and FIG. 7). For example, in the embodiment of FIGS. 1 to 5 and FIG. 7, the second housing 210 of the second resonator 200 may have the inner side surface 214 facing the side member 113 of the first housing 110 of the first resonator 100, and the side member 113 of the first housing 110 and the inner side surface 214 of the second housing 210 may be structured to face each other. In contrast, in the embodiment of FIG. 11, the inner side surface 214 of the second housing 210 may be formed to have a shape in which at least a portion thereof is spaced apart from the side member 113 of the first housing 110 by a specified distance or more. For example, when the first housing 110 of the first resonator 100 has a shape close to a square, the second resonator 200 may include the second housing 210 having a shape close to a rectangle, while having a recess of a size (or volume) large enough to accommodate the first housing 110.

In the embodiment of FIGS. 1 to 5 and FIG. 7, when the user wants to charge a plurality of electronic devices 300 and 400 at the same time, the user may perform the wireless charging operation by placing some (e.g., electronic devices 300) of the electronic devices on the first resonator 100 and placing the other electronic devices 400 on the second resonator 200. Alternatively, the wireless charging operation may be performed by placing the electronic devices 300 and 400 within the effective charging distance (or effective charging area) from the first resonator 100 and the second resonator 200. In the embodiment of FIG. 11, when the user wants to charge the plurality of electronic devices 300 and 400 at the same time, the user may perform the wireless charging operation by placing the electronic devices 300 and 400 on top of the first resonator 100 and/or the second resonator 200 or by placing the electronic devices 300 and 400 within the effective charging distance (or effective charging area) from the first resonator 100 and the second resonator 200. In addition, in the embodiment of FIG. 11, the wireless charging operation may be performed by placing the electronic devices 300 and 400 in a portion of the recess of the second resonator 200 that is not occupied by the first resonator 100, as illustrated in the drawings. In this way, the embodiment of the disclosure may provide the user with an experience of a new charging environment.

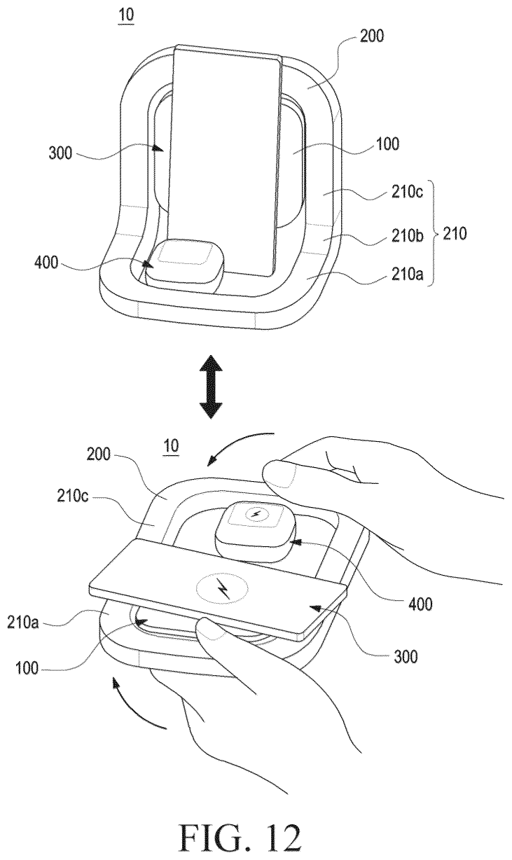

FIG. 12 illustrates an example of changing the shape of a coil in the wireless power transmission device 10 according to an embodiment.

In addition to the method of changing the position of a ferrite as the method of changing the impedance of the wireless power transmission device 10 described above, it is also possible to change the impedance of the wireless power transmission device 10 by changing the shape of a coil.

For example, as illustrated in FIG. 12, the second housing 210 of the second resonator 200 in the wireless power transmission device 10 may include a shape-variable material (e.g., urethane, rubber, or resin), and the second coil 220 disposed inside the second housing 210 may also be configured to have a variable shape. When the user applies an external force to the second resonator 200 including the second coil 220 and the second housing 210 which are variable in shape, the shape of the second resonator 200 may be deformed, thereby changing the impedance of the wireless power transmission device 10.

For example, referring to FIG. 12, when the user holds and bends the wireless power transmission device 10 according to the embodiment illustrated in FIG. 11 with both hands, the second housing 210 and the second coil 220 disposed inside the second housing 210 may be bent together, and the user may reconfigure the second housing 210 and the second coil 220 into a new user-desired shape. Compared to FIG. 11 in which the first resonator 100 and the second resonator 200 both include the first housing 110 and the second housing 210 that are parallel to the xy plane, the second resonator 200 may be configured to have at least a portion parallel to the xy plane and at least another portion perpendicular to the xy plane by applying an external force to the second housing 210 in FIG. 12.

According to an embodiment, the shape of the wireless power transmission device 10 according to the embodiment illustrated in FIG. 11 and the shape of the wireless power transmission device 10 whose shape is changed in FIG. 12 may be alternately used according to the change of the embodiment. It should be noted that the embodiment illustrated in FIG. 12 in which the shape of the second resonator 200 is changed is only one example, and various other embodiments are available.

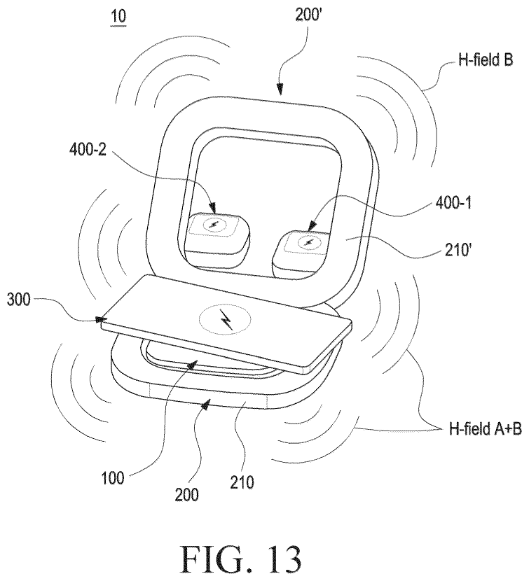

FIG. 13 illustrates a modification example of the wireless power transmission device 10 according to an embodiment.

The wireless power transmission device 10 illustrated in FIG. 13 may further include a third resonator 200′ connected to the second resonator 200, in addition to the wireless power transmission device 10 having the same structure as the first resonator 100 and the second resonator 200 described above with reference to FIGS. 1 to 5 and FIG. 7, and.

The third resonator 200′ may be similar to the second resonator 200 in shape and role. The third resonator 200′ may also include a housing and at least one coil included inside the housing. However, a recess formed in the third resonator 200′ may not accommodate the first resonator 100. Further, the housing of the third resonator 200′ may be connected to the second resonator 200, but may have a shape in which it is obliquely connected at a predetermined angle from the second resonator 200. In this case, when the user wants to charge a plurality of electronic devices 300 and 400 simultaneously, the user may perform the wireless charging operation by placing some of the electronic devices (e.g., electronic device 300) on top of the first resonator 100 and/or the second resonator 200, and placing the other electronic devices (e.g., electronic devices 400-1 and 400-2) under the third resonator 200′. In this case, since a plurality of electronic devices 400-1 and 400-2 may be freely placed under the third resonator 200′, the plurality of electronic devices 400-1 and 400-2 may be easily charged at the same time. Although the electronic device (e.g., electronic device 300) placed within the effective charging distance (or effective charging area) on or around the first resonator 100 and/or the second resonator 200 is charged by the influence of the magnetic field H-field A+B formed by the first resonator 100 and the second resonator 200, the electronic devices 400-1 and 400-2 placed under the third resonator 200′ may be charged by the influence of a magnetic field H-field B formed by the third resonator 200′.

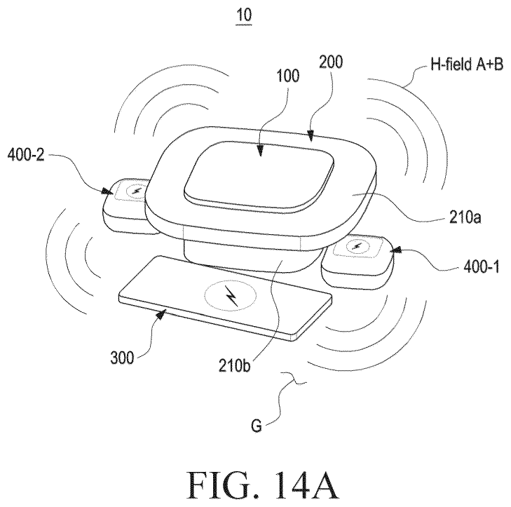

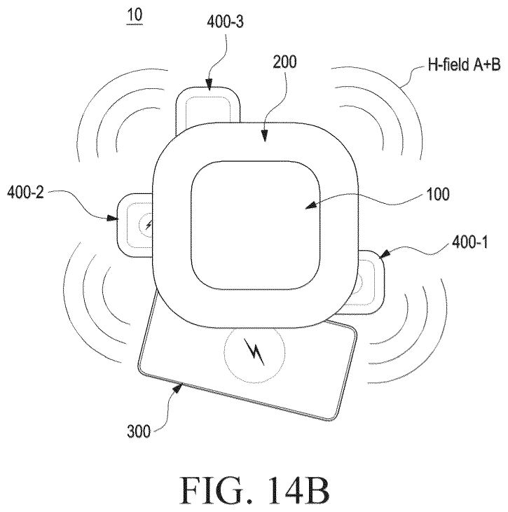

FIG. 14A is a perspective view illustrating a modification example of the wireless power transmission device 10 according to an embodiment. FIG. 14A is a front view illustrating the modification example of the wireless power transmission device 10 according to an embodiment.

At least a portion of the second housing 210 of the second resonator 200 may form the recess for accommodating the first housing 110 of the first resonator 100 therein, and at least a portion thereof may support the first housing 110 to be located at a predetermined height from the ground. According to an embodiment, the wireless power transmission device 10 may include the first resonator 100 and the second resonator 200, and the second housing 210 of the second resonator 200 may include a flat portion 210a on which the second coil 220 is disposed, and a support portion 210b supporting the flat portion 210a so that the flat portion 210a is spaced apart from the ground G by a predetermined height. According to another embodiment, the second housing 210 may be configured to have a shape that faces the ground in some state, and change its shape so that it is spaced apart from the ground by a predetermined height by the user's manipulation or automatically when needed.

As illustrated in FIGS. 14A and 14B, while the first resonator 100 and the second resonator 200 are coupled to each other, the wireless power transmission device 10 may form an area of the extended magnetic field H-field A+B. Compared to the embodiment illustrated in FIG. 1, the first coil 120 of the first resonator 100 and the second coil 220 of the second resonator 200 may form the area of the extended magnetic field H-field A+B, when they are disposed at a predetermined height apart from a ground G.

In the embodiment illustrated in FIGS. 14A and 14B, electronic device(s) 300, 400-1, and 400-2 may also be placed within the effective charging distance (or effective charging area) on or around the first resonator 100 and the second resonator 200 in the wireless power transmission device 10. In FIGS. 14A and 14B, the electronic device(s) 300, 400-1, and 400-2 may be placed on the rear surface of the flat portion 210a. According to an embodiment, the electronic device(s) 300, 400-1, and 400-2 may be placed on the rear surface of the flat portion 210a, wherein they may be placed at a position that at least partially overlaps the flat portion 210a in which the second coil 220 is disposed. The degree of freedom for placing a plurality of electronic devices 300, 400-1, and 400-2 on or around the first resonator 100 and the second resonator 200 may be increased. Further, a location where high charging efficiency may be obtained may also be secured more easily.

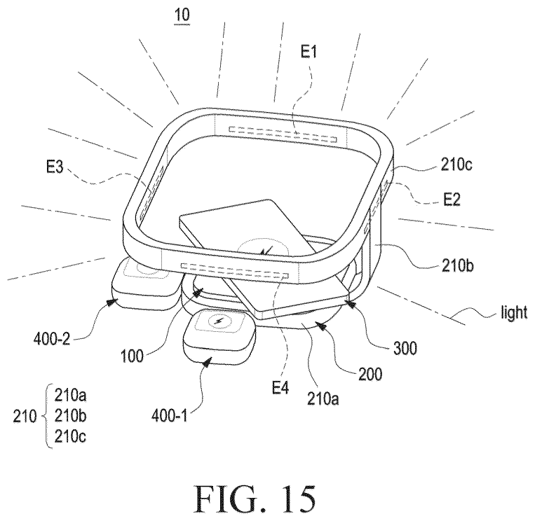

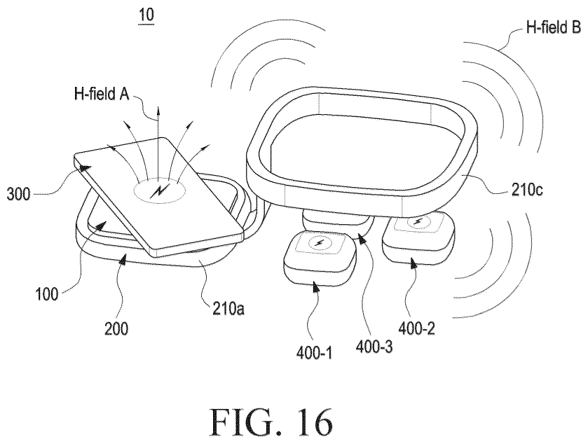

FIG. 15 illustrates a modification example of the wireless power transmission device 10 according to an embodiment. FIG. 16 illustrates a modification example of the wireless power transmission device 10 according to an embodiment.

At least a portion of the second housing 210 of the second resonator 200 may form the recess for accommodating the first housing 110 of the first resonator 100 therein, and at least another portion of the second housing may be disposed at a predetermined distance in the height direction from the first housing 110. In the wireless power transmission device 10, the second housing 210 may include at least a portion shaped to surround the first resonator 100, another portion extending in the height direction (Z-axis direction) from the portion surrounding the first resonator 100, and a third portion in which the second coil 220 is disposed spaced apart from the first coil 120 in the height direction.

Referring to FIG. 15, the second resonator 200 may be configured to perform the wireless power transmission function at a position spaced apart from the first resonator 100 in the height direction by a predetermined distance in addition to the portion surrounding the first resonator 100. The second housing 210 may include a flat portion 210a surrounding the first resonator 100, a support portion 210b extending from the flat portion 210a surrounding the first resonator 100, and a portion 210c including the second coil 220.

According to the embodiment illustrated in FIG. 15, it is possible to simultaneously perform the wireless power transmission function by placing the electronic devices 300, 400-1, and 400-2 within the effective charging distance (or effective charging area) on or around the first resonator 100, and also to perform the charging function by placing the electronic devices 300, 400-1, and 400-2 at a longer distance (or wider area) than the effective charging distance (or effective charging area) of the first resonator 100.

Further, according to an embodiment, the wireless power transmission device 10 may implement not only the wireless power transmission function, but also the function of providing lighting around the wireless power transmission device 10, as illustrated in FIG. 15. For example, at least one light emitting body (e.g., first to fourth light emitting bodies E1, E2, E3, and E4) may be disposed in the portion 210c where the second coil 220 of the wireless power transmission device 10 is accommodated, thereby providing lighting around the wireless power transmission device 10.

Therefore, higher usability of an electronic device as well as a more diverse wireless charging experience may be provided to the user.

FIG. 16 is another modification example of FIG. 15, and it should be noted that the shape of the wireless power transmission device 10 may be changed in various ways.

The wireless power transmission device 10 of the disclosure according to the above-described embodiments may provide a resonance-type wireless charging technology. The wireless power transmission device 10 of the disclosure may be formed such that the first resonator 100 may be accommodated in the recess of the second resonator 200. The wireless power transmission device 10 using the first resonator 100 and the second resonator 200 may form a coupling coefficient k of up to 0.5 for, for example, the external electronic devices 300 and 400. Considering that the coupling coefficient k is typically formed as 0.5 to 0.7 in the electromagnetic induction method, and remains at the level of 0.1 to 0.2 in the resonance method based on the conventionally known technology, the disclosure may provide a significantly increased effect compared to the conventional method. The wireless power transmission device 10 of the disclosure may provide a wider charging area than in the conventional known resonance-type wireless charging technology, and increase user convenience and charging efficiency due to the higher coupling coefficient.

The electronic devices 300 and 400 according to various embodiments of the disclosure may be various types of devices. The electronic devices may include, for example, a portable communication device (e.g., a smartphone), a wearable device, a camera, a computer device, a portable multimedia device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases. As used herein, such terms as “1^{st}” and “2^{nd}”, or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with”, “coupled to”, “connected with”, or “connected to” another element (e.g., a second element), it means that the element may be coupled with the other element directly (e.g., wired connection), wirelessly, or via a third element.

As used in connection with various embodiments of the disclosure, the term “module” may include a unit implemented in hardware, software, or firmware, and can interchangeably be used with other terms, for example, logic, logic block, part, or circuitry. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to an embodiment of the disclosure, the wireless power transmission device 10 may be provided. The wireless power transmission device 10 may include the first resonator 100 including the first housing 110 and the first coil 120 disposed inside the first housing 110 and capable of wirelessly transmitting power to the electronic devices 300 and 400 in a magnetic resonance method, and the second resonator 200 including the second housing 210 configured to surround at least a portion of the first housing 110 and the second coil 220 disposed inside the second housing 210 and capable of wirelessly transmitting power to the electronic devices 300 and 400 in the magnetic resonance method, when coupled to the first resonator 100.

According to an embodiment, when the second resonator 200 has the same resonant frequency as the first resonator 100 while the first resonator 100 is at least partially accommodated in the recess s provided in the second resonator 200, the second resonator 200 may be coupled to the first resonator 100.

According to an embodiment, the recess may include an opening, a groove, or a hole.

According to an embodiment, the first coil 120 and the second coil 220 may form magnetic fields at least partially in the same direction.

According to an embodiment, the first coil 120 and the second coil 220 may be disposed at least partially on the same plane.

According to an embodiment, the second coil 220 may be formed in a ring shape.

According to an embodiment, the first resonator 100 may include a first ferrite fixedly disposed in the first housing 110.

According to an embodiment, the second resonator 200 may include a second ferrite configured to have a variable position.

According to an embodiment, the second resonator 200 may be configured to enable the second housing 210 and the second coil 220 to have variable shapes.

According to an embodiment, the first resonator 100 may be connected to a power source, and the second resonator 200 may be provided as an extended module substantially extending a first effective charging area by being coupled by the first resonator 100.

According to an embodiment, the first resonator 100 may include an impedance matching circuit and a first control circuit for controlling a frequency of the first coil.

According to an embodiment, the second resonator 200 may include a second control circuit for controlling a frequency of the second coil.

According to an embodiment, the first resonator 100 and the second resonator 200 may further include the at least one sensor 123 and 223 for measuring a transmission voltage or a transmission current.

According to an embodiment, at least a portion of the second housing of the second resonator may form a recess for accommodating the first housing of the first resonator, and at least another portion of the second housing may support the first housing to be located at a predetermined height from a ground.

According to an embodiment, at least a portion of the second housing of the second resonator may form a recess for accommodating the first housing of the first resonator, and at least another portion of the second housing may be disposed to be spaced apart from the first housing in a height direction by a predetermined distance.

According to an embodiment of the disclosure, a wireless power transmission device may be provided. The wireless power transmission device may include a first resonator including a first housing and a first coil disposed inside the first housing, and a second resonator including a second housing providing a space in which at least a portion of the first resonator is accommodable, and a second coil disposed inside the second housing and coupled to the first coil. The first resonator may provide a first effective charging area to an external device, and the second resonator may provide a second effective charging area to a second external electronic device, when coupled to the first resonator.

While specific embodiments have been described above in the detailed description of the disclosure, it will be apparent to those skilled in the art that many modifications may be made without departing from the scope of the disclosure.

What is claimed is:

1. A wireless power transmission device comprising:
a first resonator comprising a first housing and a first coil inside the first housing, the first resonator being configured to wireless transmit power to an electronic device; and
a second resonator comprising a second housing around at least a portion of the first housing, and a second coil inside the second housing, the second resonator being configured to wireless transmit power to the electronic device, in a state in which the second resonator is coupled to the first resonator.

2. The wireless power transmission device of claim 1, wherein in a state in which the second resonator and the first resonator have a same resonant frequency while the first resonator is at least partially accommodated in a recess provided in the second resonator, the second resonator is coupled to the first resonator.

3. The wireless power transmission device of claim 2, wherein the recess comprises an opening, a groove, or a hole.

4. The wireless power transmission device of claim 2, wherein the first coil and the second coil are configured to form magnetic fields at least partially in a same direction.

5. The wireless power transmission device of claim 2, wherein the first coil and the second coil are disposed at least partially on the same plane.

6. The wireless power transmission device of claim 1, wherein the second coil has a ring shape.

7. The wireless power transmission device of claim 1, wherein the first resonator further comprises a first ferrite fixedly disposed in the first housing.

8. The wireless power transmission device of claim 7, wherein the second resonator further comprises a second ferrite configured to have a variable position.

9. The wireless power transmission device of claim 1, wherein the second resonator is configured to enable the second housing and the second coil to have variable shapes.

10. The wireless power transmission device of claim 1, wherein the first resonator is connected to a power source, and
wherein the second resonator is provided as an extended module substantially extending a first effective charging area by being coupled to the first resonator.

11. The wireless power transmission device of claim 1, wherein the first resonator further comprises an impedance matching circuit and a first control circuit for controlling a frequency of the first coil.

12. The wireless power transmission device of claim 1, wherein the second resonator further comprises a second control circuit configured to control a frequency of the second coil.

13. The wireless power transmission device of claim 1, wherein each of the first resonator and the second resonator further comprises at least one sensor configured to measure a transmission voltage or a transmission current.

14. The wireless power transmission device of claim 1, wherein at least a portion of the second housing of the second resonator comprises a recess configured to accommodate the first housing of the first resonator, and at least another portion of the second housing supports the first housing to be at a predetermined height from a ground.

15. The wireless power transmission device of claim 1, wherein at least a portion of the second housing of the second resonator comprises a recess for configured to accommodate the first housing of the first resonator, and at least another portion of the second housing is spaced apart from the first housing in a height direction by a predetermined distance.

16. A wireless power transmission device comprising:
a first resonator comprising a first housing and a first coil inside the first housing, and
a second resonator comprising a second housing providing a space in which at least a portion of the first resonator is accommodable, and a second coil inside the second housing and coupled to the first coil.

17. The wireless power transmission device of claim 16, wherein the first resonator provides a first effective charging area to an external device, and
wherein the second resonator provides a second effective charging area to a second external electronic device, when coupled to the first resonator.

18. The wireless power transmission device of claim 16, wherein the first coil and the second coil are at least partially on the same plane.

19. The wireless power transmission device of claim 16, wherein the second coil has a ring shape.

20. The wireless power transmission device of claim 16, wherein the first coil and the second coil are configured to form magnetic fields at least partially in the same direction.
